(19) United States
(12) Patent Application Publication
(10) Pub. No.: US 2025/0389768 A1
(43) Pub. Date: Dec. 25, 2025

(54) TEST CONNECTOR

(71) Applicant: ISC CO., LTD, Gyeonggi-do (KR)

(72) Inventors: Dong Gyun WOO, Gyeonggi-do (KR); Eon Joong KIM, Gyeonggi-do (KR); Byeung Ju LEE, Gyeonggi-do (KR); Sang Hyun JOO, Gyeonggi-do (KR); Kyu Hyeon KIM, Gyeonggi-do (KR)

(21) Appl. No.: 18/851,126

(22) PCT Filed: Mar. 24, 2023
(86) PCT No.: PCT/KR2023/003930

§ 371 Date: Sep. 26, 2024

(30) Foreign Application Priority Data
Mar. 28, 2022 (KR) 10-2022-0038077

(51) Int. Cl. G01R 31/28

(52) U.S. Cl. CPC G01R 31/2889

(57) ABSTRACT

A test connector is disposed between a test apparatus and a device under test. The connector includes a housing, a signal conduction portion, an insulation support portion, and an air insulation portion. The signal conduction portion is disposed in a through hole of the housing in an up-and-down direction, and is spaced apart from the through hole. The insulation support portion surrounds the signal conduction portion between the through hole and the signal conduction portion, and positions the signal conduction portion coaxially with a central axis of the through hole. The insulation support portion has a thickness less than a thickness of the housing. The air insulation portion is a space formed by an inner peripheral surface of the through hole, an outer peripheral surface of the signal conduction portion, and an upper surface or a lower surface of the insulation support portion.

### TECHNICAL FIELD

The present disclosure relates to a test connector, which is disposed between a test apparatus and a device under test and is used for testing of the device under test.

### BACKGROUND

To test a device under test such as a semiconductor device, a connector disposed between a test apparatus and the device under test has been used in the art. The connector used for testing of the device under test electrically connects the test apparatus and the device under test. A pogo pin or a conductive rubber sheet is known as such a connector. The conductive rubber sheet has conduction portions, in which a multiple number of conductive particles are gathered in an up-and-down direction, and which can be elastically deformed by a pressing force of the device under test.

A semiconductor device used in a mobile communication device must be tested with respect to a radio frequency (RF) characteristic of a high frequency. Since the conductive rubber sheet has an RF characteristic better than the pogo pin due to a thin thickness thereof, the conductive rubber sheet has been used for testing of an RF characteristic of a semiconductor device. By way of example, Japanese Patent Application Publication No. 2004-335450 proposes a connector that can handle a high-frequency signal.

To prevent loss, distortion, and cross talk of signals during testing of an RF characteristic of a high frequency, the conduction portion is required to be disposed in a frame with a coaxial structure. To dispose the conduction portion in the frame with a coaxial structure, a conventional conductive rubber sheet has an insulation portion maintaining the conduction portion coaxially. Where the conductive rubber sheet used for testing shows an impedance that does not match an impedance of the device under test and an impedance of the test apparatus, a large signal loss occurs in the conductive rubber sheet due to signal reflection. For impedance matching, the conventional conductive rubber sheet uses the frame made of a metallic material, and the conduction portion is supported by the insulation portion surrounding the conduction portion and insulating the conduction portion with respect to the frame.

However, in the conventional conductive rubber sheet, the insulation portion, which completely surrounds the conduction portion and has a high dielectric permittivity, deteriorates a signal delivery characteristic of the conduction portion, thereby making the impedance matching difficult. Further, since the insulation portion restricts expansion of the conduction portion when a terminal of the device under test presses the conduction portion, the conduction portion cannot have an appropriate elastic restoring force.

Regarding the coaxial arrangement of the conduction portion for testing of the RF characteristic of a high frequency, the frame and the conduction portion must maintain a uniform distance therebetween to achieve matching of appropriate impedances. Where the terminals of the device under test have a fine pitch, a diameter of the conduction portion cannot be enlarged beyond a predetermined dimension in order to prevent a short circuit between the frame and the conduction portion. In contrast, to increase contact areas between the terminal of the device under test and the conduction portion and between the terminal of the test apparatus and the conduction portion, the diameter of the conduction portion is required to be large within a range in which a short circuit does not occur between the conduction portion and the frame. However, the conventional conductive rubber sheet does not satisfy both of these two design requirements.

### SUMMARY

One embodiment of the present disclosure provides a test connector that prevents loss, distortion, and cross talk of signals during testing of an RF characteristic of a high frequency. One embodiment of the present disclosure provides a test connector that realizes a low dielectric permittivity around a conduction portion and can facilitate impedance matching. One embodiment of the present disclosure provides a test connector that can increase an elastic restoring force and a diameter of a conduction portion positioned in a coaxial arrangement.

Embodiments of the present disclosure relate to a test connector, which is disposed between a test apparatus and a device under test and is used for testing of the device under test. The connector according to one embodiment includes a housing, a signal conduction portion, an insulation support portion, and an air insulation portion. The housing has a first through hole perforated in an up-and-down direction. The signal conduction portion is configured to be conductive in the up-and-down direction and is disposed in the first through hole in the up-and-down direction so as to be spaced apart from an inner peripheral surface of the first through hole. The insulation support portion is formed between the first through hole and the signal conduction portion so as to surround the signal conduction portion in a circumferential direction with respect to a central axis of the first through hole. The insulation support portion is configured to support and insulate the signal conduction portion such that the signal conduction portion is positioned coaxially with the central axis. The insulation support portion has an up-and-down directional thickness less than an up-and-down directional thickness of the housing. The air insulation portion is located between the inner peripheral surface of the first through hole and an outer peripheral surface of the signal conduction portion. The air insulation portion is a space formed by the inner peripheral surface of the first through hole, the outer peripheral surface of the signal conduction portion, and an upper surface or a lower surface of the insulation support portion.

In one embodiment, the air insulation portion may be formed as an annular groove that surrounds the outer peripheral surface of the signal conduction portion in the circumferential direction at least one of an upper end or a lower end of the first through hole.

In one embodiment, the air insulation portion may include a first air insulation portion and a second air insulation portion, which are located at an upper end and a lower end of the first through hole, respectively. The connector of one embodiment may further comprise an elastic portion that is formed in the first air insulation portion along the inner peripheral surface of the first through hole so as to be spaced apart from the outer peripheral surface of the signal conduction portion.

In one embodiment, the elastic portion may be made of silicone rubber or silicone rubber containing a multiple number of pores.

The connector of one embodiment may further comprise an elastic portion, which is disposed in the first air insulation portion so as to surround the outer peripheral surface of the signal conduction portion and contains a multiple number of pores.

In one embodiment, the housing may have a second through hole, which is spaced apart from the first through hole in a horizontal direction and is perforated in the up-and-down direction. The connector of one embodiment may further comprise a ground conduction portion, which is disposed in the second through hole in the up-and-down direction and is configured to be conductive in the up-and-down direction.

In one embodiment, an upper end of the ground conduction portion may protrude with respect to an upper surface of the housing, and a lower end of the ground conduction portion may protrude with respect to a lower surface of the housing.

In one embodiment, the signal conduction portion comprises a multiple number of first conductive particles gathered so as to be capable of conducting in the up-and-down direction, and a first elastic substance maintaining the multiple number of first conductive particles in the up-and-down direction. The ground conduction portion comprises a multiple number of second conductive particles gathered so as to be capable of conducting in the up-and-down direction, and a second elastic substance maintaining the multiple number of second conductive particles in the up-and-down direction.

The connector of one embodiment may further comprise an insulation sheet coupled to a portion in a vicinity of a lower end of the signal conduction portion to support the signal conduction portion in the up-and-down direction, and coupled to a lower surface of the housing. The insulation support portion and the signal conduction portion are integrally formed and the signal conduction portion and the insulation sheet are integrally formed, thereby constituting a conduction module that is removably coupled to the housing. The insulation support portion may be fitted into the first through hole.

In one embodiment, the signal conduction portion includes: a concealed portion surrounded by the insulation support portion; and an exposed portion not surrounded by the insulation support portion and surrounded by the air insulation portion, wherein the exposed portion has a diameter equal to or greater than a diameter of the concealed portion and forms an upper end or a lower end of the signal conduction portion.

In one embodiment, the diameter of the exposed portion may be in a range of 1 times to less than or equal to 2.5 times the diameter of the concealed portion.

In one embodiment, the housing includes first and second housings that are stacked and bonded in the up-and-down direction. A portion of the first through hole is formed in the first housing, and a remainder portion of the first through hole is formed in the second housing. The insulation support portion and the concealed portion are disposed in the portion of the first through hole, and the exposed portion is disposed in the remainder portion of the first through hole. The air insulation portion is formed to surround the exposed portion in a state where the first and second housings are stacked in the up-and-down direction. The connector of one embodiment may further comprises a ground conduction portion, which is disposed in the second through hole of the housing in the up-and-down direction and is configured to be conductive in the up-and-down direction. The ground conduction portion may include a first portion disposed in the first housing, and a second portion disposed in the second housing and bonded to the first portion.

In one embodiment, the housing includes first, second, and third housings that are stacked and bonded in the up-and-down direction. An intermediate portion of the first through hole is formed in the first housing, an upper portion of the first through hole located on the intermediate portion is formed in the second housing, and a lower portion of the first through hole located under the intermediate portion is formed in the third housing. The insulation support portion and the concealed portion are disposed in the intermediate portion of the first through hole, and the exposed portion is disposed in the upper portion of the first through hole and the lower portion of the first through hole. The air insulation portion is formed so as to surround the exposed portion in a state where the first, second, and third housings are stacked in the up-and-down direction. The connector of one embodiment may further comprise a ground conduction portion, which is disposed in the second through hole in the up-and-down direction and is configured to be conductive in the up-and-down direction. The ground conduction portion includes a first portion disposed in the first housing, a second portion disposed in the second housing and bonded to the first portion, and a third portion disposed in the third housing and bonded to the first portion. The connector of one embodiment may further comprise an elastic portion that is formed along an inner peripheral surface of the upper portion of the first through hole of the second housing so as to be spaced apart from the outer peripheral surface of the signal conduction portion.

In one embodiment, the up-and-down directional thickness of the insulation support portion may be in a range of 50% to 90% of the up-and-down directional thickness of the housing.

In one embodiment, the insulation support portion may be made of one of silicone rubber, polyimide resin, polyetherimide resin, and polytetrafluoroethylene resin.

In one embodiment, the housing is made of a metallic material or nonmetallic material. The metallic material may be aluminum or stainless steel. The nonmetallic material may be polyimide resin or standard epoxy resin.

According to one embodiment of the present disclosure, the insulation support portion supporting the signal conduction portion is disposed in only a portion of the first through hole, and a portion of the signal conduction portion not surrounded by the insulation support portion is surrounded by the air insulation portion filled with air having a low dielectric permittivity. Accordingly, a low dielectric permittivity is realized around the signal conduction portion. Thus, signal loss in the signal conduction portion is reduced, and the signal conduction portion allows appropriate matching of impedances.

According to one embodiment of the present disclosure, a portion of the signal conduction portion surrounded by the air insulation portion can be elastically deformed without restriction from the insulation support portion. Accordingly, the signal conduction portion can be formed so as to have as large a diameter as possible at the upper and lower ends thereof within a range in which the signal conduction portion is not short-circuited with the housing, and the signal conduction portion can be formed so as to have an appropriate elastic restoring force. Further, an area of the signal conduction portion, which makes contact with the terminal of the device under test and the terminal of the test apparatus, can be increased.

### BRIEF DESCRIPTION OF DRAWINGS

FIG. 1 schematically shows an example where a connector according to one embodiment is used.

FIG. 2 is a sectional view showing a portion of a connector according to a first embodiment of the present disclosure.

FIG. 3 is a sectional perspective view showing the portion of the connector shown in FIG. 2.

FIG. 4 is a sectional view showing another example of the connector according to the first embodiment.

FIG. 5 is a sectional view showing a portion of a connector according to a second embodiment of the present disclosure.

FIG. 6 is a sectional perspective view showing the portion of the connector shown in FIG. 5.

FIG. 7 is a sectional view showing another example of the connector according to the second embodiment.

FIG. 8 is a sectional view showing a portion of a connector according to a third embodiment of the present disclosure.

FIG. 9 is a sectional perspective view showing the portion of the connector shown in FIG. 8.

FIG. 10 is a sectional view showing another example of the connector according to the third embodiment.

FIG. 11 is a sectional view showing a portion of a connector according to a fourth embodiment of the present disclosure.

FIG. 12 is a sectional perspective view showing the portion of the connector shown in FIG. 11.

FIG. 13 is a sectional view showing a portion of a connector according to a fifth embodiment of the present disclosure.

FIG. 14 is a plan view showing the portion of the connector shown in FIG. 13.

FIG. 15 is a sectional view showing another example of the connector according to the fifth embodiment.

FIG. 16 is a sectional view showing a portion of a connector according to a sixth embodiment of the present disclosure.

FIG. 17 is an exploded sectional view showing the portion of the connector shown in FIG. 16.

FIG. 18 is a sectional view showing a portion of a connector according to a seventh embodiment of the present disclosure.

FIG. 19 is an exploded sectional view showing the portion of the connector shown in FIG. 18.

FIG. 20 is a sectional view showing another example of the connector according to the seventh embodiment.

FIG. 21 is a sectional view showing a portion of a connector according to an eighth embodiment of the present disclosure.

FIG. 22 is an exploded sectional view showing the portion of the connector shown in FIG. 21.

FIG. 23 is a sectional view showing another example of the connector according to the eighth embodiment.

FIG. 24 is a sectional view showing a portion of a connector according to a ninth embodiment of the present disclosure.

FIG. 25 is an exploded sectional view showing the portion of the connector shown in FIG. 24.

### DETAILED DESCRIPTION

Embodiments of the present disclosure are illustrated for the purpose of explaining the technical idea of the present disclosure. The scope of the rights according to the present disclosure is not limited to the embodiments presented below or the detailed descriptions of such embodiments.

All technical terms and scientific terms used in the present disclosure include meanings that are commonly understood by those of ordinary skill in the technical field to which the present disclosure pertains unless otherwise defined. All terms used in the present disclosure are selected for the purpose of describing the present disclosure more clearly, and are not selected to limit the scope of the rights according to the present disclosure.

Expressions such as “comprising,” “including,” “having,” and the like used in the present disclosure are to be understood as open-ended terms having the possibility of encompassing other embodiments, unless otherwise mentioned in the phrase or sentence containing such expressions.

Singular expressions described in the present disclosure may encompass plural expressions unless otherwise stated, which will also apply to singular expressions recited in the claims.

Expressions such as “first,” “second,” etc. used in the present disclosure are used to distinguish a plurality of elements from one another, and are not intended to limit an order or importance of the elements.

In the present disclosure, the description that one element is “connected” or “coupled” to another element should be understood to indicate that one element may be directly connected or coupled to another element, or that one element may be connected or coupled to another element via a new element.

A directional term “upward” used in the present disclosure is based on a direction in which a connector is positioned with respect to a test apparatus, while the directional term “downward” means a direction opposite to the upward direction. A directional term “up-and-down direction” used in the present disclosure may include an upward direction and a downward direction, but it is to be understood not to mean a particular one direction between the upward direction and the downward direction.

Hereinafter, the embodiments are described with reference to examples shown in the accompanying drawings. Like reference symbols in the accompanying drawings denote like or corresponding elements. Further, in the following descriptions of the embodiments, redundant descriptions for the same or corresponding elements may be omitted. However, even if the descriptions of the elements are omitted, such elements are not intended to be excluded in any embodiment.

The embodiments described below and the examples shown in the accompanying drawings are directed to a test connector (hereinafter, briefly referred to as a connector) used for testing of a device under test. The connector of the embodiments is disposed between a test apparatus and the device under test when testing the device under test, and may be used for testing of the device under test. By way of example, in a post-process of manufacturing processes of a semiconductor device, the connector of the embodiments may be used for final testing of the semiconductor device. However, the test example to which the connector of the embodiments are applied is not limited to the above-described example.

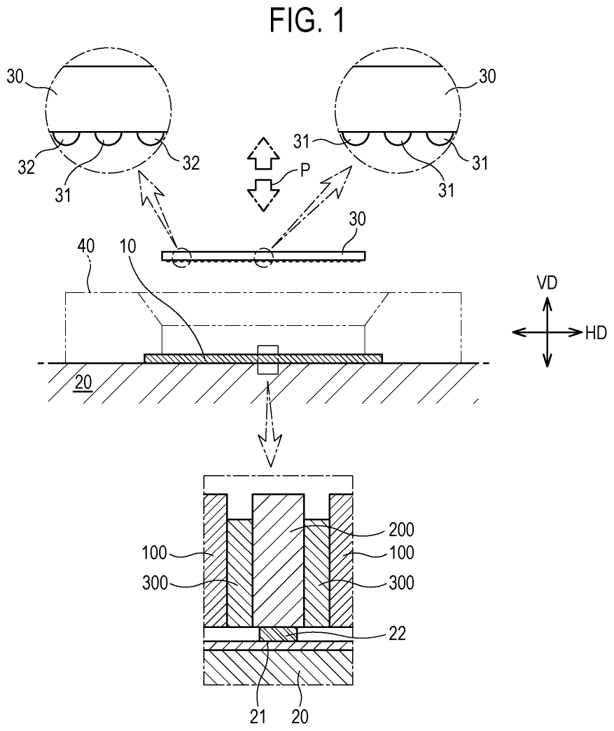

FIG. 1 shows an example where the connector according to one embodiment is used. FIG. 1 schematically shows shapes of the connector, the test apparatus, and the device under test.

Referring to FIG. 1, a connector 10 according to one embodiment is a sheet-shaped structure, and is disposed between a test apparatus 20 and a device under test 30. By way of example, the connector 10 may be positioned on the test apparatus 20 by a test socket 40. The test socket 40 may be removably mounted on the test apparatus 20. The test socket 40 accommodates the device under test 30, which is transferred to the test apparatus 20 manually or by a transfer device, therein, and aligns the device under test 30 with respect to the connector 10. During testing of the device under test 30, the connector 10 is contacted with the test apparatus 20 and the device under test 30 in an up-and-down direction VD, and electrically connects the test apparatus 20 and the device under test 30 to each other. By way of example, the connector 10 may be disposed between the device under test 30 and the test apparatus 20 for an RF testing of high-frequency of the device under test 30.

The device under test 30 may be a semiconductor device that is obtained by packaging a semiconductor IC chip and numerous terminals into a hexahedral form by using a resin material. By way of example, the device under test 30 may be a semiconductor device used for a mobile communication device, but is not limited thereto. The device under test 30 has, at its underside, a multiple number of terminals. The multiple number of terminals of the device under test 30 may be a signal terminal 31 and a ground terminal 32. The device under test 30 may have only the signal terminal 31, or may have both of the signal terminal 31 and the ground terminal 32.

The test apparatus 20 may test various operational characteristics of the device under test 30. The test apparatus 20 may have a board on which the testing is performed, and a testing circuit 21 for the testing of the device under test may be provided in the board. Further, the testing circuit 21 has a multiple number of terminals 22 that are electrically connected to the terminals of the device under test through the connector 10. The terminals 22 of the test apparatus 20 are capable of transmitting electrical test signals and receiving response signals.

The signal terminal 31 of the device under test 30 is electrically connected to one of the terminals 22 of the test apparatus 20 through the connector 10, and the ground terminal 32 of the device under test 30 is electrically connected to another one of the terminals 22 of the test apparatus 20 through the connector 10. During testing of the device under test, the connector 10 electrically connects the respective terminals 31 and 32 of the device under test to the respective terminals 22 of the test apparatus in the up-and-down direction VD, and the testing of the device under test 30 is performed by the test apparatus 20 through the connector 10.

The connector 10 includes a housing 100, a signal conduction portion 200, and an insulation support portion 300. The housing 100 is attached to the test socket 40, and may be disposed in a horizontal direction HD. The housing 100 may constitute a main body of the connector, in which the signal conduction portion 200 is disposed in the up-and-down direction VD. In the connector 10, the signal conduction portion 200 and the insulation support portion 300 may comprise an elastic substance. The signal conduction portion 200 is configured to be conductive in the up-and-down direction VD. The signal conduction portion 200 may be contacted, at its upper end, with the signal terminal 31 of the device under test 30, and may be contacted, at its lower end, with the terminal 22 of the test apparatus 20. The insulation support portion 300 supports the signal conduction portion 200 in the up-and-down direction VD, and insulates the signal conduction portion 200 with respect to the housing 100.

During testing of the device under test 30, a pressing force P may be applied to the connector 10 through the device under test 30 by a machine device or manually. Due to the pressing force P, the terminals 31 and 32 of the device under test and the connector 10 may be contacted with each other in the up-and-down direction VD, and the connector 10 and the terminal 22 of the test apparatus may be contacted with each other in the up-and-down direction VD. As the signal terminal 31 of the device under test receiving the pressing force P presses the signal conduction portion 200 downward, the signal conduction portion 200 may be elastically deformed so as to contract in the up-and-down direction and to expand in the horizontal direction. As the pressing force P is applied to the connector 10, the signal conduction portion 200 is pressed in the up-and-down direction, and the signal conduction portion 200 is contacted with the signal terminal 31 of the device under test and the terminal 22 of the test apparatus. When the pressing force P is removed from the connector 10, the signal conduction portion 200 can be restored into its original shape.

The connector 10 may include a plurality of signal conduction portions 200. A planar arrangement of the signal conduction portions 200 may vary depending on an arrangement of the terminals of the device under test 30. By way of example, the signal conduction portions 200 may be arranged in the form of one matrix, or in the form of one or more pairs of matrices.

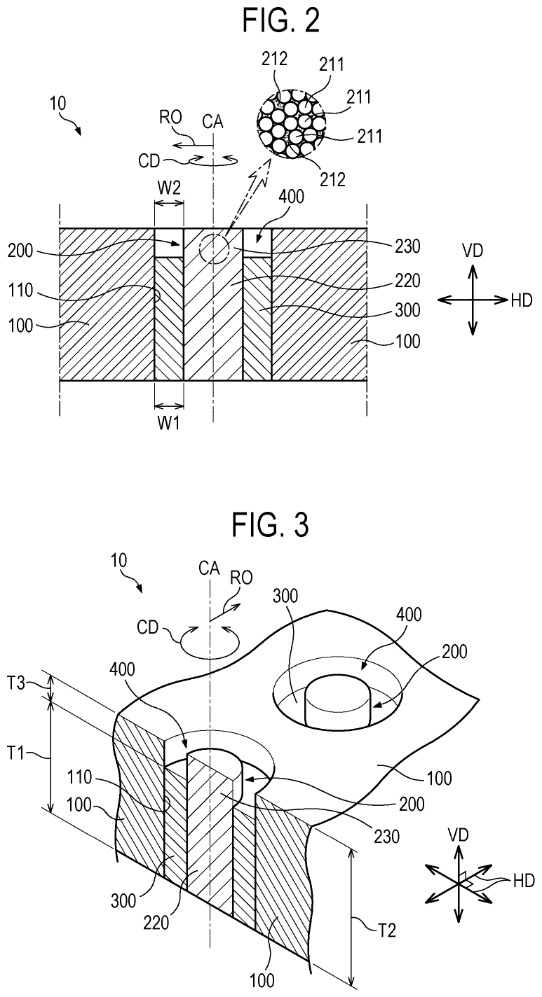

Reference is made to FIGS. 2 to 25 for descriptions of the connector according to the embodiments. FIGS. 2 to 25 schematically show shapes of the elements of the connector. The shapes shown in FIGS. 2 to 25 are merely examples selected for purposes of understanding the embodiments.

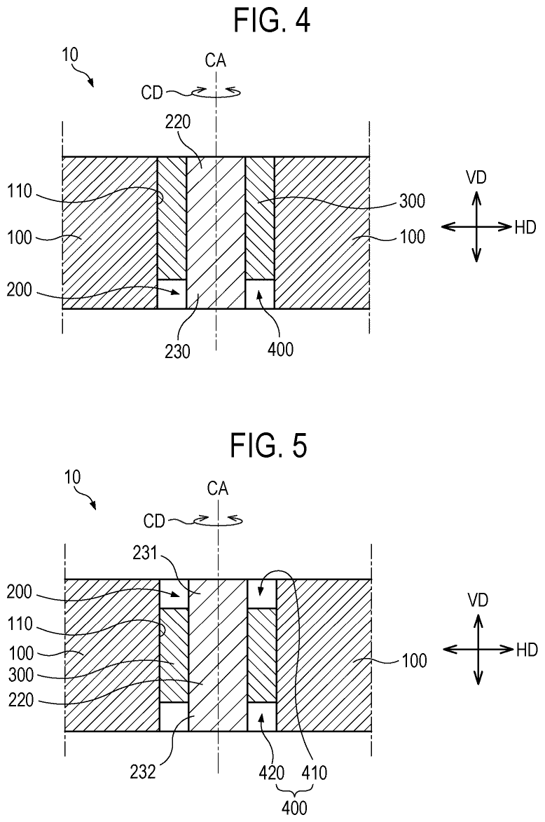

FIG. 2 is a sectional view showing a portion of a connector according to a first embodiment of the present disclosure, and FIG. 3 is a sectional perspective view showing the portion of the connector shown in FIG. 2. FIG. 4 is a sectional view showing another example of the connector according to the first embodiment. Reference is made to FIGS. 2 to 4 for descriptions of the connector according to the first embodiment.

Referring to FIGS. 2 and 3, the connector 10 according to one embodiment includes the housing 100, the signal conduction portion 200 configured to be conductive in the up-and-down direction VD, and the insulation support portion 300 supporting the signal conduction portion 200 and insulating the signal conduction portion 200 with respect to the housing 100.

The housing 100 is a structure for disposing the signal conduction portion 200 in the up-and-down direction VD. The housing 100 may be formed in a shape of a thin flat plate, and is disposed in the horizontal direction HD orthogonal to the up-and-down direction VD. The housing 100 may be made of a metallic material or a nonmetallic material having high hardness. The metallic material constituting the housing 100 may be aluminum or stainless steel, but is not limited thereto. The nonmetallic material constituting the housing 100 may be polyimide resin (PI resin) or standard epoxy resin (FR4 resin), but is not limited thereto.

To dispose the signal conduction portion 200 in the housing 100, the housing 100 has a first through hole 110 formed in the up-and-down direction VD. The first through hole 110 passes through the housing 100 in the up-and-down direction VD. The first through hole 110 is perforated through the housing 100 in the up-and-down direction VD from a lower surface of the housing 100 up to an upper surface of the housing 100.

The signal conduction portion 200 is disposed in the first through hole 110 in the up-and-down direction VD coaxially with a central axis CA of the first through hole 110. The signal conduction portion 200 is disposed in the first through hole 110 so as to be spaced apart from an inner peripheral surface of the first through hole 110 (e.g., such that an outer peripheral surface of the signal conduction portion and the inner peripheral surface of the first through hole are spaced apart from each other in a radial direction with respect to the central axis CA). The signal conduction portion 200 is configured to be conductive in the up-and-down direction, thereby performing signal delivery in the up-and-down direction VD between the test apparatus and the device under test. The signal conduction portion 200 may have a cylindrical shape extending in the up-and-down direction VD.

The signal conduction portion 200 is contacted, at its upper end, with the signal terminal of the device under test, and is contacted, at its lower end, with the terminal of the test apparatus. Therefore, an up-and-down directional conduction path is formed via the signal conduction portion 200 between the signal terminal of the device under test and the terminal of the test apparatus, which correspond to one signal conduction portion 200. The test signal of the test apparatus may be delivered from the terminal of the test apparatus through the signal conduction portion 200 to the terminal of the device under test, and the response signal of the device under test may be delivered from the terminal of the device under test through the signal conduction portion 200 to the terminal of the test apparatus.

The signal conduction portion 200 is not only conductive in the up-and-down direction, but also is capable of contracting and expanding by the pressing force. The signal conduction portion 200 includes a multiple number of first conductive particles 211 and a first elastic substance 212.

The multiple number of first conductive particles 211 are gathered in a column shape so as to be capable of conducting in the up-and-down direction VD, and the neighboring first conductive particles 211 may be contacted with each other so as to be capable of conducting in any direction. The multiple number of first conductive particles 211 gathered so as to be capable of conducting in the up-and-down direction function as a conductor for performing signal delivery between the terminal of the test apparatus and the signal terminal of the device under test. The first conductive particles 211 may be made of a highly conductive metallic material. Alternatively, the first conductive particles 211 may have a form that the aforementioned highly conductive metallic material is coated on a core made of an elastic resin material or a metallic material.

The first elastic substance 212 is in a state of being hardened, and has elasticity. The first elastic substance 212 maintains the first conductive particles 211 in the up-and-down direction VD such that the first conductive particles 211 are gathered in the column shape. The first elastic substance 212 is filled between the first conductive particles 211. The first elastic substance 212 is integrally formed with the first conductive particles 211, thereby constituting the signal conduction portion 200. The first elastic substance 212 may have insulation property. By way of example, the first elastic substance 212 may be hardened silicone rubber, but is not limited thereto.

The signal conduction portion 200 including the first elastic substance 212 has elasticity, and is elastically deformable in the up-and-down direction VD and the horizontal direction HD. During testing of the device under test, the signal terminal of the device under test presses the signal conduction portion 200 downward by a pressing force. In a pressed state of the signal conduction portion, the signal conduction portion 200 can be elastically deformed so as to be compressed downward while slightly expanding in the horizontal direction HD. When the pressing force is removed, the signal conduction portion 200 can be elastically restored from the pressed state to its original shape (i.e., a non-pressed state). The signal conduction portion 200 can be reversibly deformed into the non-pressed state and the pressed state.

The signal conduction portion 200 is positioned by the insulation support portion 300 coaxially with the central axis CA of the first through hole 110. The insulation support portion 300 is configured to position the signal conduction portion 200 in the first through hole 110 coaxially with the central axis CA. Further, the insulation support portion 300 is configured to support the signal conduction portion 200 in the up-and-down direction VD and to insulate the signal conduction portion 200 with respect to the housing 100.

The insulation support portion 300 is disposed between the outer peripheral surface of the signal conduction portion 200 and the inner peripheral surface of the first through hole 110. The insulation support portion 300 is formed so as to fill an annular space formed between the inner peripheral surface of the first through hole 110 and the outer peripheral surface of the signal conduction portion 200. The insulation support portion 300 may take a pipe shape corresponding to the aforementioned annular space. The insulation support portion 300 is formed so as to surround the signal conduction portion 200 in a circumferential direction CD with respect to the central axis CA between the inner peripheral surface of the first through hole 110 and the outer peripheral surface of the signal conduction portion 200. A width W1 of the insulation support portion 300 in a radially outward direction RO with respect to the central axis CA may be constant along the circumferential direction CD. Accordingly, the signal conduction portion 200 supported by the insulation support portion 300 can be disposed coaxially with the central axis CA in the first through hole 110.

The insulation support portion 300 may be made of a material having insulation property and elasticity. By way of example, the insulation support portion 300 may be made of one of silicone rubber, polyimide resin (PI resin), polyetherimide resin (Ultem resin), and polytetrafluoroethylene resin (Teflon resin), but is not limited thereto.

The insulation support portion 300 has an up-and-down directional thickness T1. The up-and-down directional thickness T1 of the insulation support portion may be defined as a distance between two surfaces of the insulation support portion 300 in the up-and-down direction (an upper surface and a lower surface of the insulation support portion). The insulation support portion 300 has the up-and-down directional thickness T1 less than an up-and-down directional thickness T2 of the housing 100. The up-and-down directional thickness T2 of the housing 100 may be defined as a distance between the upper surface and the lower surface of the housing in the up-and-down direction. In the connector of the embodiments, the thickness T1 of the insulation support portion may be in a range of 50% to 90% of the thickness T2 of the housing.

Since the thickness T1 of the insulation support portion is less than the thickness T2 of the housing, in the first through hole 110, a portion of the outer peripheral surface of the signal conduction portion 200 is not surrounded by the insulation support portion 300 and is exposed. Thus, a space filled with air is formed along an exposed surface of the outer peripheral surface of the signal conduction portion 200, which is not surrounded by the insulation support portion 300. Such an exposed surface is spaced apart from the inner peripheral surface of the first through hole 110 through an empty space in a radially inward direction of the central axis. In the present disclosure, the space filled with air in the first through hole 110 is referred to as an air insulation portion.

Referring to FIGS. 2 and 3, the air insulation portion 400 may be located at an upper end of the first through hole 110, and may be formed so as to open in an upward direction. Thus, the air insulation portion 400 is filled with air. The air insulation portion 400 is located between the inner peripheral surface of the first through hole 110 and the outer peripheral surface of the signal conduction portion 200 in the horizontal direction. The air insulation portion 400 may be a space that is defined and formed by a portion of the inner peripheral surface of the first through hole 110, a portion of the outer peripheral surface of the signal conduction portion 200, and an up-and-down directional surface of the insulation support portion 300 (e.g., an upper surface of the insulation support portion). The air insulation portion 400 surrounds a portion of the signal conduction portion 200, which is not surrounded by the insulation support portion 300 (e.g., a portion of the outer peripheral surface located in the vicinity of an upper end of the signal conduction portion), in the circumferential direction CD.

As shown in FIGS. 2 and 3, the air insulation portion 400 may be formed as an annular groove that surrounds the outer peripheral surface located in the vicinity of the upper end of the signal conduction portion 200 at the upper end of the first through hole 110 in the circumferential direction CD. In the air insulation portion 400 formed as the annular groove, the air insulation portion 400 has a width W2 in the radially outward direction RO. The air insulation portion 400 having an annular shape surrounds the signal conduction portion 200 in a state where a center of the air insulation portion is located on the central axis CA of the first through hole. Since the up-and-down directional thickness T1 of the insulation support portion is 50% to 90% of the thickness T2 of the housing, an up-and-down directional thickness T3 of the air insulation portion may be in a range of 10% to 50% of the up-and-down directional thickness T2 of the housing.

The outer peripheral surface of the signal conduction portion 200 may be distinguished into a portion surrounded by the insulation support portion 300 and a portion surrounded by the air insulation portion 400. Accordingly, the signal conduction portion 200 may include a concealed portion 220 surrounded by the insulation support portion 300, and an exposed portion 230 not surrounded by the insulation support portion and surrounded by the air insulation portion 400. The concealed portion 220 and the exposed portion 230 located in the up-and-down direction form the signal conduction portion. The concealed portion 220 is concealed by the insulation support portion 300 and is not exposed. The exposed portion 230 may be a portion of the signal conduction portion that excludes the concealed portion 220. A diameter of the signal conduction portion at the exposed portion 230 may be equal to a diameter of the signal conduction portion at the concealed portion 220 or be greater than the diameter of the signal conduction portion at the concealed portion 220. An outer peripheral surface of the exposed portion 230 is located opposite to the inner peripheral surface of the first through hole 110 in the radially outward direction RO. An upper end surface of the exposed portion 230 forms the upper end of the signal conduction portion 200.

The signal conduction portion 200 is disposed in the first through hole 110 coaxially with the central axis CA in a state of being supported by the insulation support portion 300. In the signal conduction portion 200 supported by the insulation support portion 300, a central axis of the signal conduction portion in the up-and-down direction becomes coaxial with the central axis CA of the first through hole 110. Further, the pipe-shaped insulation support portion 300 and the annular air insulation portion 400 are disposed coaxially with the central axis CA. Due to the coaxial arrangement of the signal conduction portion 200, during the high-frequency testing of the device under test, loss and distortion of the signals passing through the signal conduction portion 200 can be reduced, and a crosstalk can be prevented.

A dielectric permittivity of a portion, which disposes the signal conduction portion 200 coaxially and surrounds the signal conduction portion 200, may affect the signal delivery performance and the impedance matching of the signal conduction portion 200. As the dielectric permittivity of such a portion is lower, the signal conduction portion 200 can have reduced signal loss, and the impedance of the signal conduction portion 200 can be better matched with an impedance of the device under test and an impedance of the test circuit of the test apparatus.

According to the connector of one embodiment, the insulation support portion 300 having a relatively high dielectric permittivity does not have a thickness corresponding to an up-and-down height of the first through hole 110 (or a thickness of the housing), and is disposed only in a partial area of the first through hole 110 in the up-and-down direction. Since the insulation support portion 300 occupies only the partial area of the first through hole 110, the air insulation portion 400 is disposed in the remainder area of the first through hole 110. The air insulation portion 400 is filled with air that has a dielectric permittivity considerably less than the dielectric permittivity of the insulation support portion, for example, the air having a dielectric permittivity of about 1. Accordingly, in the connector of the one embodiment, a portion surrounding the signal conduction portion 200 in the circumferential direction of the central axis CA has a very low dielectric permittivity, and the signal conduction portion 200 can have a reduced signal loss and an improved high-frequency characteristic, and can show better impedance matching.

A portion of the signal conduction portion 200 not surrounded by the insulation support portion 300 (e.g., the exposed portion 230) is surrounded by the air insulation portion 400. Thus, when the pressing force is applied to the signal conduction portion during testing of the device under test, the exposed portion 230 surrounded by the air insulation portion 400 can be easily expanded in the horizontal direction without restriction from the insulation support portion, and the signal conduction portion 200 may have a good elastic restoration force.

Further, the exposed portion 230 of the signal conduction portion 200 is spaced apart from the inner peripheral surface of the first through hole 110 through the air insulation portion 400. Thus, the signal conduction portion 200 can have a large diameter within a limit of preventing a short circuit between the signal conduction portion and the housing while maintaining a constant spaced distance for the impedance matching between the signal conduction portion and the inner peripheral surface of the first through hole 110. Since the signal conduction portion 200 can have a larger diameter, the signal conduction portion 200 can be contacted with the terminal of the device under test and the terminal of the test apparatus with a wider contact area, and can have an improved signal conduction performance.

FIG. 4 shows another example of the connector according to one embodiment. Referring to FIG. 4, the air insulation portion 400 may be located at the lower end of the first through hole 110. The air insulation portion 400 may be a space that is defined and formed by a portion of the inner peripheral surface of the first through hole 110, a portion of the outer peripheral surface of the signal conduction portion 200, and an up-and-down directional surface of the insulation support portion 300 (e.g., a lower surface of the insulation support portion). The air insulation portion 400 may be formed as an annular groove that surrounds the outer peripheral surface of the signal conduction portion 200 at the lower end of the first through hole 110 in the circumferential direction CD. The signal conduction portion 200 has the exposed portion 230 forming the lower end of the signal conduction portion, and the exposed portion 230 is not surrounded by the insulation support portion and is surrounded by the air insulation portion 400.

The connector according to one embodiment shown in FIGS. 2 to 4 may be manufactured by various methods according to various pitches of the terminals of the device under test.

By way of example, the housing 100 of a flat plate is prepared, and the first through hole 110 may be formed in the housing 100 by drilling or a laser at each position where the signal conduction portion is formed. In a case where the housing 100 is made of aluminum, the housing 100 may be anodized such that an insulating oxide film is formed on the inner peripheral surface of the first through hole 110 and the surface of the housing 100 in order to improve strength and durability of the connector.

As an example, a structure in which the signal conduction portion 200 and the insulation support portion 300 are formed integrally may be fitted into the first through hole 110 of the housing 100, thereby manufacturing the connector. The signal conduction portion 200 and the insulation support portion 300 may be formed integrally by means of a molding die. A liquid molding material, in which the first conductive particles are dispersed in the first elastic material of a liquid state, is injected into the molding die, and the signal conduction portion 200 may be molded using a magnetic field. Thereafter, the signal conduction portion 200 and a liquid elastic material constituting the insulation support portion 300 are disposed in the molding die, and the signal conduction portion 200 and the insulation support portion 300 may be molded integrally. Where the elastic material constituting the insulation support portion 300 is the same as the first elastic substance of the signal conduction portion 200, the signal conduction portion 200 and the insulation support portion 300 may be molded integrally by using one molding die.

As another example, after the housing 100 is formed so as to have the first through hole 110, a cylinder-shaped elastic object may be formed in the first through hole 110 by means of the elastic material of the insulation support portion 300 such that a space to be formed as the air insulation portion remains. Thereafter, a through hole is formed by a laser in the up-and-down direction in the aforementioned elastic object filling the first through hole 110, and then the signal conduction portion 200 molded independently from the insulation support portion may be fitted into such a through hole.

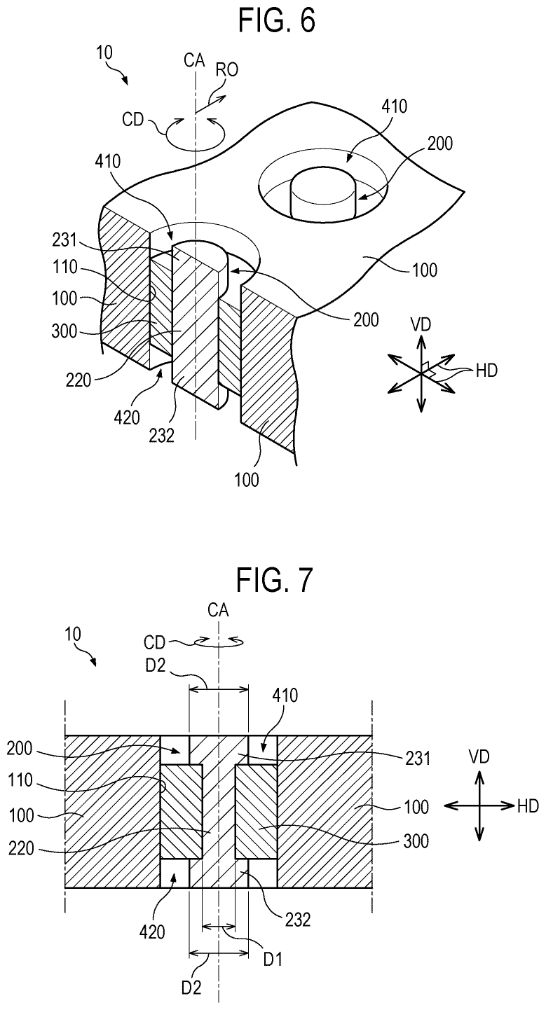

FIG. 5 is a sectional view showing a portion of a connector according to a second embodiment of the present disclosure, and FIG. 6 is a sectional perspective view showing the portion of the connector shown in FIG. 5. FIG. 7 is a sectional view showing another example of the connector according to the second embodiment. Reference is made to FIGS. 5 to 7 for descriptions of the connector according to the second embodiment.

The connector 10 according to the second embodiment has a configuration similar to the configuration of the connector according to the above-described first embodiment. The connector 10 according to the second embodiment includes the above-described housing 100 and the above-described signal conduction portion 200. The insulation support portion 300 of the connector 10 according to the second embodiment is located approximately at the middle of the first through hole 110. Therefore, the air insulation portion 400 of the connector 10 according to the second embodiment includes a pair of air insulation portions 410 and 420 that are located at the upper end and the lower end of the first through hole 110, respectively.

The pair of air insulation portions 410 and 420 are a first air insulation portion 410 located at the upper end of the first through hole 110 and a second air insulation portion 420 located at the lower end of the first through hole 110. The insulation support portion 300 may be positioned in the first through hole 110 such that the first air insulation portion 410 and the second air insulation portion 420 have the same up-and-down thickness. The exposed portion of the signal conduction portion, which is not surrounded by the insulation support portion 300 and is exposed, includes a first exposed portion 231 and a second exposed portion 232. The first exposed portion 231 is located at the upper end of the first through hole, and the second exposed portion 232 is located at the lower end of the first through hole.

Referring to FIG. 7, the signal conduction portion 200 may be configured such that a diameter of a portion surrounded by the air insulation portion is greater than a diameter of a portion surrounded by the insulation support portion. Therefore, the first and second exposed portions 231 and 232 have a diameter D2 greater than a diameter D1 of the concealed portion 220. The diameter D2 of the first and second exposed portions 231 and 232 may be in a range more than 1 times to less than or equal to 2.5 times the diameter D1 of the concealed portion. Since the diameter D2 of the first and second exposed portions 231 and 232 is greater than the diameter D1 of the concealed portion 220, a cross-sectional area of the signal conduction portion at its upper and lower ends is greater than a cross-sectional area of a portion surrounded by the insulation support portion 300 (i.e., the concealed portion). Therefore, the upper end of the signal conduction portion 200 can be contacted with the signal terminal of the device under test with a wider contact area, and the lower end of the signal conduction portion 200 can be contacted with the terminal of the test apparatus with a wider contact area. Since the respective air insulation portions surround the first and second exposed portions 231 and 232, the signal conduction portion 200 can not only have a function of good impedance matching due to the air insulation portions, but also can be contacted with the terminals with a wider contact area. Therefore, the diameter of the signal conduction portion at its upper and lower ends can be increased in the range where a short circuit does not occur between the signal conduction portion and the housing.

The connector shown in FIGS. 5 to 7 may be manufactured by a method similar to the manufacturing method of the connector shown in FIGS. 2 to 4. As one example of manufacturing the connector shown in FIG. 7, a cylinder-shaped elastic object may be formed in the first through hole 110 of the housing 100 by means of the elastic material of the insulation support portion 300 such that spaces to be formed as the air insulation portions remain. A through hole is formed in such an elastic object in the up-and-down direction by a laser, and thereafter, the signal conduction portion 200, which is formed independently from the insulation support portion and has a concavely formed middle portion, may be fitted into the through hole of the aforementioned elastic object.

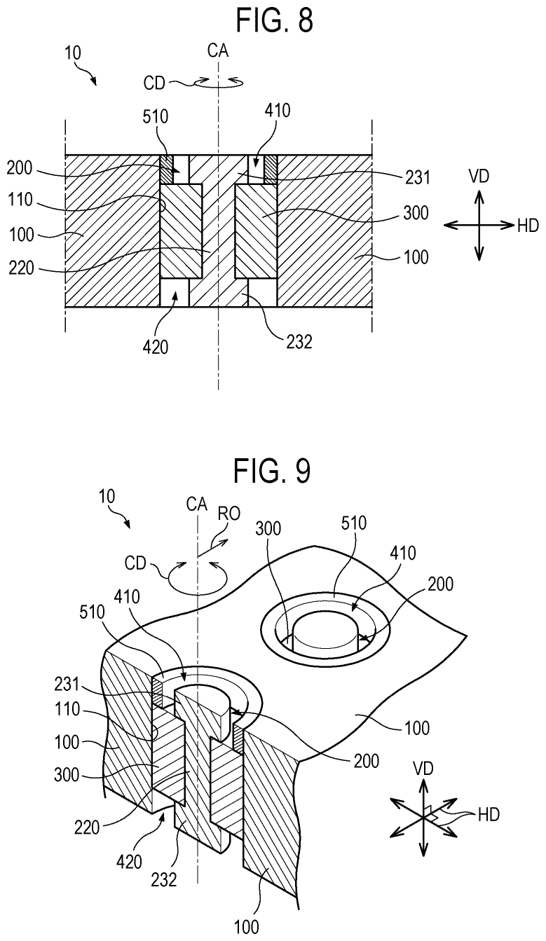

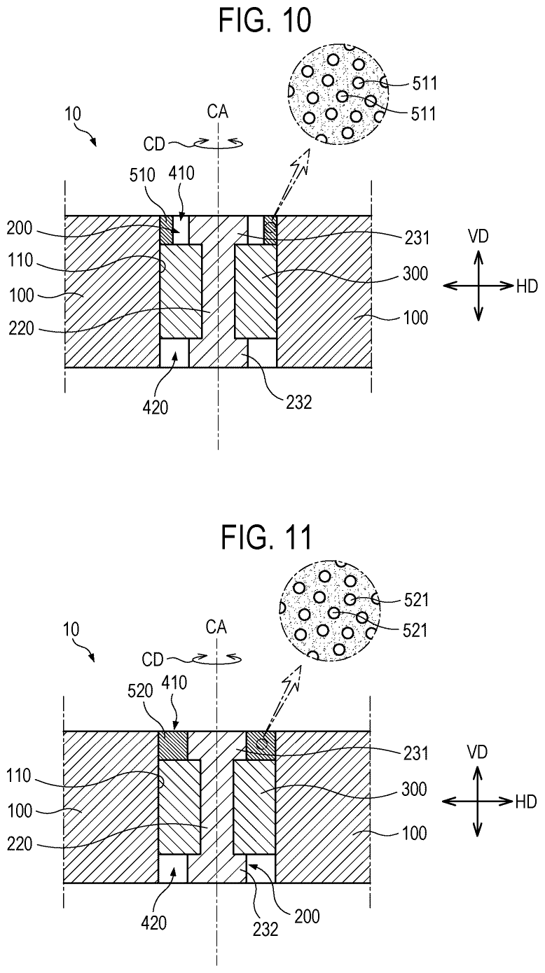

FIG. 8 is a sectional view showing a portion of a connector according to a third embodiment of the present disclosure, and FIG. 9 is a sectional perspective view showing the portion of the connector shown in FIG. 8. FIG. 10 is a sectional view showing another example of the connector according to the third embodiment. Reference is made to FIGS. 8 to 10 for descriptions of the connector according to the third embodiment.

The connector according to the third embodiment has a configuration similar to the configuration of the connector according the above-described second embodiment shown in FIG. 7. When compared with the above-described embodiment, the connector 10 according to the third embodiment includes an elastic portion 510 disposed at the upper end of the first through hole 110.

In the connector according to the third embodiment shown in FIGS. 8 and 9, the air insulation portion includes the first air insulation portion 410 located at the upper end of the first through hole 110, and the second air insulation portion 420 located at the lower end of the first through hole 110. The elastic portion 510 is provided in the first air insulation portion 410 surrounding the first exposed portion 231. The elastic portion 510 has an annular shape corresponding to the annular shape of the first air insulation portion 410. The elastic portion 510 is formed along the inner peripheral surface of the first through hole 110 so as to be spaced apart from a portion of the outer peripheral surface of the signal conduction portion 200 (the outer peripheral surface of the first exposed portion 231) in the radially outward direction RO with respect to the central axis CA. Therefore, the elastic portion 510 can occupy a portion of the space formed by the first air insulation portion 410.

As an example, the elastic portion 510 may be made of hardened silicone rubber. Alternatively, the elastic portion 510 may be made of the same material as the material of the insulation support portion 300. During testing of the device under test, the terminal of the device under test (e.g., the signal terminal of the device under test shown in FIG. 1) and the signal conduction portion may not be aligned in the up-and-down direction, and the terminal of the device under test may be contacted with the housing. The elastic portion 510 can prevent the terminal of the device under test from being directly contacted with the housing. Since the signal terminal can be contacted with the elastic portion 510 provided at the upper end of the first through hole 110 in a state where the signal terminal of the device under test and the signal conduction portion are not aligned, the elastic portion 510 can prevent the terminal of the device under test from being damaged by the housing 100.

Referring to FIG. 10, the elastic portion 510 may be made of silicone rubber containing a multiple number of pores 511. The elastic portion 510 containing the multiple number of pores 511 may be formed from liquid silicone rubber to which a foaming agent is added. By way of example, when the elastic portion 510 is formed, the foaming agent chemically reacts with the liquid silicone rubber and generates gas. The generated gas pushes the liquid material in the liquid silicone rubber. Therefore, the generated gas partially eliminates the liquid resin during molding of the elastic portion, and the multiple number of pores 511 having various sizes can be formed throughout the entirety of the elastic portion. The elastic portion 510 containing the multiple number of pores 511 may have a dielectric permittivity less than a dielectric permittivity of the elastic portion containing no pores.

In the embodiment shown in FIGS. 8 to 10, the first and second exposed portions 231 and 232 have a diameter greater than the diameter of the concealed portion 220. Thus, the signal conduction portion 200 can be contacted with the terminal of the device under test and the terminal of the test apparatus with a wider contact area. By way of example, the connector 10 provided with the elastic portion 510 can be effectively used for testing of the device under test having a narrow pitch between the terminals. Further, the connector 10 provided with the elastic portion 510 can increase the cross-sectional area of the upper and lower ends of the signal conduction portion while preventing a short circuit between the signal conduction portion and the housing. As another example, the elastic portion 510 may be provided at the upper end of the first through hole in the embodiments shown in FIGS. 2 and 6.

The connector shown in FIGS. 8 to 10 may be manufactured by a method similar to the manufacturing method of the connector shown in FIGS. 2 to 7. The elastic portion 510 may be formed by making a liquid elastic material constituting the elastic portion 510 surround the inner peripheral surface of the first through hole 110 by means of a molding die.

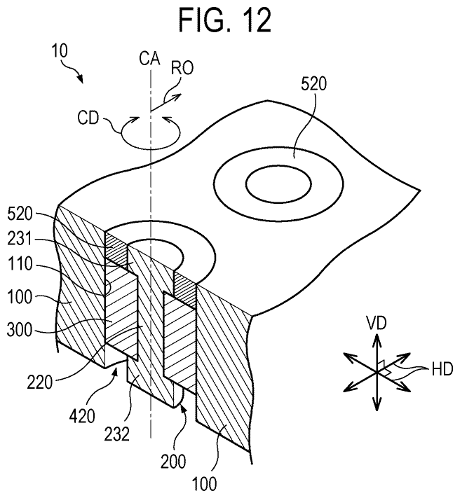

FIG. 11 is a sectional view showing a portion of a connector according to a fourth embodiment of the present disclosure, and FIG. 12 is a sectional perspective view showing the portion of the connector shown in FIG. 11. Reference is made to FIGS. 11 and 12 for descriptions of the connector according to the fourth embodiment.

The connector according to the fourth embodiment has a configuration similar to the configuration of the connector according the above-described second embodiment shown in FIG. 7. When compared with the above-described embodiment, the connector 10 according to the fourth embodiment includes an elastic portion 520, which is located at the upper end of the first through hole 110 and can prevent damage to the terminal of the device under test.

In the connector according to the fourth embodiment shown in FIGS. 11 and 12, the air insulation portion includes the first air insulation portion 410 located at the upper end of the first through hole 110, and the second air insulation portion 420 located at the lower end of the first through hole 110. The elastic portion 520, which can prevent damage to the terminal of the device under test (e.g., the signal terminal of the device under test shown in FIG. 1), is disposed in the first air insulation portion 410 surrounding the first exposed portion 231. The elastic portion 520 has an annular shape corresponding to the annular shape of the first air insulation portion 410. The elastic portion 520 is disposed in the first air insulation portion 410 so as to surround a portion of the outer peripheral surface of the signal conduction portion 200 (the outer peripheral surface of the first exposed portion 231). Therefore, the elastic portion 520 can occupy the entirety of the space formed by the first air insulation portion 410.

The elastic portion 520 may be made of a material which contains a multiple number of pores 521 and has elasticity and insulation property. The elastic portion 520 may be made of silicone rubber containing the pores 521, but is not limited thereto. The elastic portion 520 containing the multiple number of pores 521 may be molded by a method similar to the elastic portion 510 described with reference to FIG. 10.

The elastic portion 520 contains the pores 521 and can have a relatively low dielectric permittivity thereby. Since the elastic portion 520 surrounds the outer peripheral surface of the first exposed portion 231, it is possible to prevent the first conductive particles from detaching from the first exposed portion 231 due to the pressing force during testing of the device under test. Further, the elastic portion 520 can prevent the terminal of the device under test from being damaged by the housing. Further, as shown in FIGS. 11 and 12, the signal conduction portion 200 has the first and second exposed portions 231 and 232 having a diameter greater than the diameter of the concealed portion 220, and a member having a lower dielectric permittivity can be disposed around the signal conduction portion 200 due to the elastic portion 520 containing the pores 521. As another example, the elastic portion 520 may be provided at the upper end of the first through hole in the embodiments shown in FIGS. 2 and 6.

The connector shown in FIGS. 11 to 12 may be manufactured by a method similar to the manufacturing method of the connector shown in FIGS. 2 to 7. The elastic portion 520 may be formed from a forming agent and a liquid elastic material constituting the elastic portion 520 by means of a molding die so as to occupy the space of the air insulation portion.

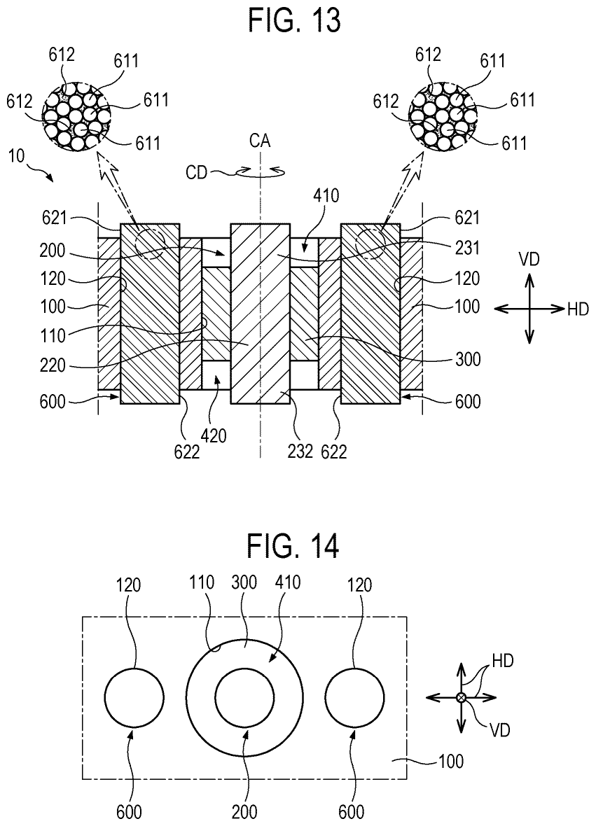

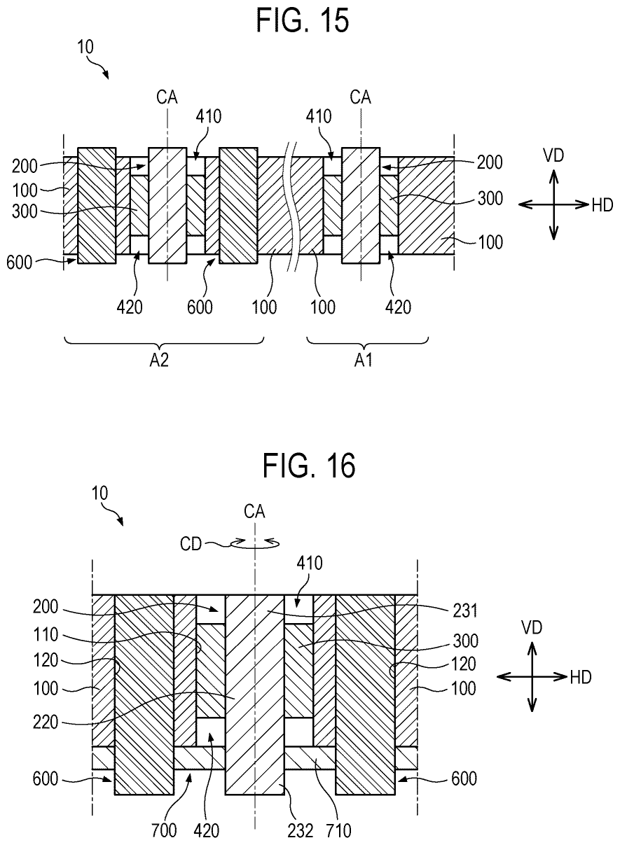

FIG. 13 is a sectional view showing a portion of a connector according to a fifth embodiment of the present disclosure, and FIG. 14 is a plan view showing the portion of the connector shown in FIG. 13. FIG. 15 is a sectional view showing another example of the connector according to the fifth embodiment. Reference is made to FIGS. 13 to 15 for descriptions of the connector according to the fifth embodiment.

In the connector according to the fifth embodiment shown in FIGS. 13 to 15, the housing and the signal conduction portion are configured similarly to the housing and the signal conduction portion of the above-described embodiments. The connector 10 according to the fifth embodiment includes a ground conduction portion 600, which is contacted with the ground terminal of the device under test (e.g., the ground terminal 32 of the device under test shown in FIG. 1) and the terminal of the test apparatus and is configured to be conductive in the up-and-down direction VD.

The housing 100 has a second through hole 120 in which the ground conduction portion 600 is disposed. The second through hole 120 is spaced apart from the first through hole 110 in the horizontal direction HD, and is formed in the up-and-down direction VD. The second through hole 120 passes through the housing 100 in the up-and-down direction VD, and is perforated through the housing 100 from the lower surface of the housing 100 up to the upper surface of the housing 100 in the up-and-down direction VD.

The ground conduction portion 600 is disposed in the second through hole 120 in the up-and-down direction VD. The ground conduction portion 600 is conductive in the up-and-down direction. The ground conduction portion 600 includes a multiple number of second conductive particles 611 and a second elastic substance 612. The multiple number second conductive particles 611 are gathered in a column shape so as to be capable of conducting in the up-and-down direction VD, and the neighboring second conductive particles 611 may be contacted with each other so as to be capable of conducting in any direction. The second conductive particles 611 of the ground conduction portion may be the same as or different from the above-described first conductive particles of the signal conduction portion 200. The second elastic substance 612 is in a hardened state, and has elasticity. The second elastic substance 612 maintains the second conductive particles 611 in the up-and-down direction VD such that the second conductive particles 611 are gathered in the column shape. The second elastic substance 612 may be filled between the second conductive particles 611. The second elastic substance 612 may be the same as or different from the above-described first elastic substance of the signal conduction portion.

Referring to FIG. 13, an upper end of the ground conduction portion 600 protrudes with respect to the upper surface of the housing 100, and a lower end of the ground conduction portion 600 protrudes with respect to the lower surface of the housing 100. Thus, the ground conduction portion 600 has an upper end protruding portion 621 and a lower end protruding portion 622. Further, the upper end and the lower end of the signal conduction portion 200 may be positioned at the same level as the upper end and the lower end of the ground conduction portion 600. The upper end protruding portion 621 and the lower end protruding portion 622 can permit the ground conduction portion 600 to expand in the horizontal direction, and can improve an elastic restoring force of the ground conduction portion 600. That is, when the ground terminal of the device under test presses the ground conduction portion 600 during testing of the device under test, the ground conduction portion can be deformed at the upper end protruding portion 621 and the lower end protruding portion 622 in the horizontal direction. As another example, the upper end and the lower end of the ground conduction portion 600 may be positioned at the same level as the upper surface and the lower surface of the housing 100.

In a case where the housing 100 is made of the above-described metallic material, the second conductive particles 611 of the ground conduction portion 600 are contacted with the second through hole 120, and the housing 100 and the ground conduction portion 600 can be electrically contacted with each other. Therefore, the housing 100 may function as a single shielding plate.

Referring to FIG. 15, a first area A1 with the signal conduction portion 200 disposed therein and a second area A2 with both the signal conduction portion 200 and the ground conduction portion 600 disposed therein may be provided in one connector 10. The first area A1 may include a plurality of signal conduction portions 200. In the second area A2, a plurality of ground conduction portions 600 may be disposed around one signal conduction portion 200. Alternatively, an area with a plurality of ground conduction portions 600 gathered therein may be provided in one connector 10. The area including a plurality of signal conduction portions 200, the area including both the signal conduction portion 200 and the plurality of ground conduction portions 600, and the area including the plurality of ground conduction portions 600 may be provided in the connector 10 depending on the design for the terminal arrangement of the device under test.

In the connector shown in FIGS. 13 to 15, the signal conduction portion, the insulation support portion, and the air insulation portion may be formed by a method similar to the manufacturing method of the above-described embodiments. By way of example, the second through hole 120 may be formed together with the first through hole 110 in the housing 100. The second through hole 120 may be formed in the housing 100 by drilling or a laser. The ground conduction portion 600 may be formed after forming the signal conduction portion and the insulation support portion, or independently from the signal conduction portion and the insulation support portion. By way of example, the ground conduction portion 600 may be formed in the housing 100 by injecting a liquid molding material, in which the second conductive particles are dispersed in the second elastic substance of a liquid state, to the second through hole 120, and gathering the second conductive particles in the up-and-down direction in the second through hole 120 through application of a magnetic field. Alternatively, the ground conduction portion 600, which is molded independently by means of a molding die, may be fitted to the second through hole 120.

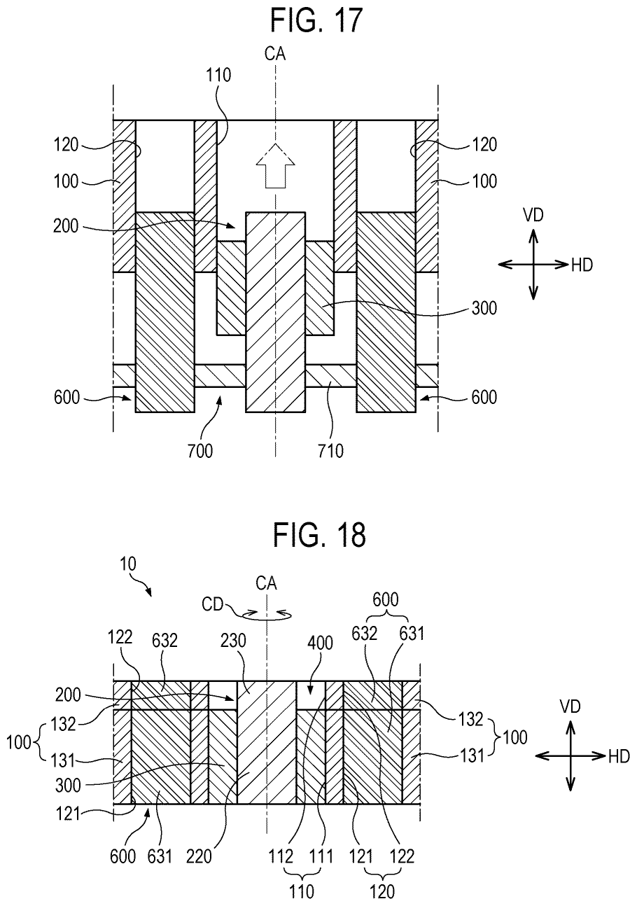

FIG. 16 is a sectional view showing a portion of a connector according to a sixth embodiment of the present disclosure, and FIG. 17 is an exploded sectional view showing the portion of the connector shown in FIG. 16. Reference is made to FIGS. 16 and 17 for descriptions of the connector according to the sixth embodiment.

In the connector according to the sixth embodiment shown in FIGS. 16 and 17, the signal conduction portion is configured similarly to the signal conduction portion of the above-described embodiment described with reference to FIG. 5. The signal conduction portion 200 is disposed coaxially in the first through hole 110 by the insulation support portion 300. The first air insulation portion 410 is formed at the upper end of the first through hole 110, and the second air insulation portion 420 is formed at the lower end of the first through hole 110. The first air insulation portion 410 is formed by a portion of the inner peripheral surface of the first through hole 110, a portion of the outer peripheral surface of the signal conduction portion 200 (the outer peripheral surface of the first exposed portion 231), and the upper surface of the insulation support portion 300. The second air insulation portion 420 is formed by a portion of the inner peripheral surface of the first through hole 110, a portion of the outer peripheral surface of the signal conduction portion 200 (the outer peripheral surface of the second exposed portion 232), and the lower surface of the insulation support portion 300.

In the connector 10 according to the sixth embodiment, the signal conduction portion 200 conductive in the up-and-down direction may be coupled to the housing 100 by a modularized structure. Referring to FIGS. 16 and 17, the connector 10 includes an insulation sheet 710 coupled to the lower surface of the housing 100. The insulation sheet 710 and the housing 100 may be coupled by bonding an upper surface of the insulation sheet 710 and the lower surface of the housing 100. The coupling of the housing 100 and the insulation sheet 710 may be performed by a bonding method using an adhesive, but is not limited thereto.

In the connector 10, the insulation sheet 710 is located at a side facing the test apparatus, and is disposed in the horizontal direction HD so as to constitute a horizontal surface of the connector 10. The insulation sheet 710 is coupled to a portion in the vicinity of the lower end of the signal conduction portion 200 in the horizontal direction HD, thereby supporting the signal conduction portion 200 in the up-and-down direction VD. Further, the insulation sheet 710 is coupled to a portion in the vicinity of the lower end of the ground conduction portion 600 in the horizontal direction HD, thereby supporting the ground conduction portion 600 in the up-and-down direction VD. The insulation sheet 710 may be formed as a single elastic object, and functions to support the signal conduction portion 200 and the ground conduction portion 600 in the up-and-down direction VD. The insulation sheet 710 may be made of a material having insulation property such as silicone rubber, polyimide resin, or standard epoxy resin (FR4 resin).

FIGS. 16 and 17 show an example where the insulation sheet 710 is coupled to the ground conduction portion 600. As another example, only one signal conduction portion 200 or only a plurality of signal conduction portions 200 may be coupled to the insulation sheet 710.

In the connector of one embodiment, the signal conduction portion 200 and the insulation sheet 710 may be formed as an integrally-formed structure, and the insulation support portion 300 and the signal conduction portion 200 may be formed integrally. Therefore, the signal conduction portion 200 and the insulation sheet 710 formed integrally may constitute a single conduction module 700 that performs conduction in the up-and-down direction, and the insulation support portion 300 may be integrally formed with the signal conduction portion 200 of such a single conduction module. Further, such a single conduction module 700 may be removably coupled to the housing 100.

The conduction module 700 may be manufactured from a molding die independently from the housing 100. In the molded conduction module 700, the insulation support portion 300 is integrally formed with the signal conduction portion 200. The molded conduction module 700 may be removably coupled to the housing 100. For example, as shown in FIG. 17, when the conduction module 700 is coupled to the housing 100, the insulation support portion 300 integrally formed with the signal conduction portion 200 may be fitted to the first through hole 110 of the housing from below to upward. The insulation support portion 300 fitted to the first through hole 110 positions the signal conduction portion 200 coaxially with the central axis CA. Further, in a state where the insulation support portion 300 is fitted to the first through hole 110 as shown in FIG. 16, the first air insulation portion 410 and the second air insulation portion 420 are formed at the upper end and the lower end of the first through hole, respectively. Thus, the air insulation portion decreasing the dielectric permittivity in the signal delivery of the signal conduction portion 200 can be easily formed in the first through hole 110.

The connector of one embodiment may include one or more above-described conduction modules. Some conduction modules of a plurality of conduction modules may include the signal conduction portion 200 and the insulation sheet 710 that are formed integrally. Other conduction modules of the plurality of conduction modules may include the signal conduction portion 200, the ground conduction portion 600, and the insulation sheet 710 that are formed integrally. Since such conduction modules are removably coupled to the housing, it is possible to replace only a conduction module, which has a damaged signal conduction portion among a multiple number of signal conduction portions provided in the connector.

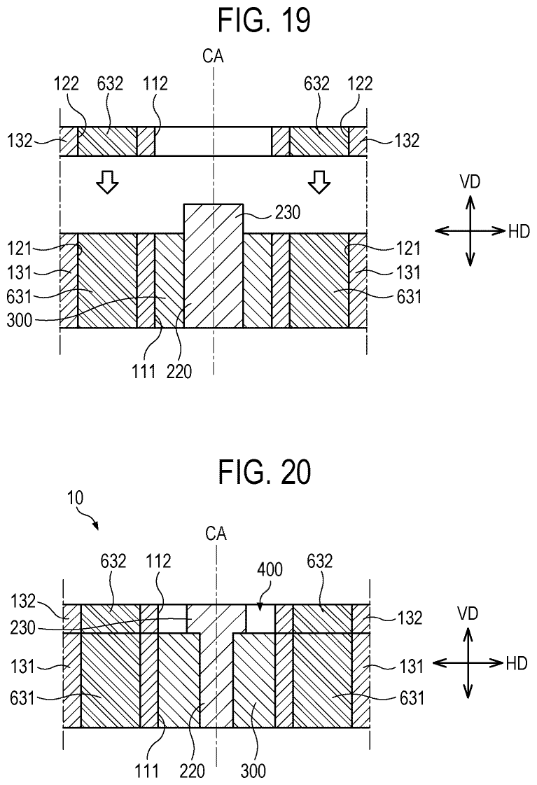

FIG. 18 is a sectional view showing a portion of a connector according to a seventh embodiment of the present disclosure, and FIG. 19 is an exploded sectional view showing the portion of the connector shown in FIG. 18. FIG. 20 is a sectional view showing another example of the connector according to the seventh embodiment. Reference is made to FIGS. 18 to 20 for descriptions of the connector according to the seventh embodiment.

The connector according to the seventh embodiment has a configuration similar to the configuration of the connector described with reference to the FIG. 2, and includes the ground conduction portion of the connector of the embodiment described with reference to FIG. 13. In the connector 10 according to the seventh embodiment, the housing 100 has a structure where two portions are stacked. Therefore, the air insulation portion decreasing the dielectric permittivity in the signal transmission of the signal conduction portion can be easily formed in the first through hole of the housing due to the stacked structure of the housing.

Referring to FIGS. 18 and 19, the housing 100 includes first and second housings 131 and 132 that are stacked in the up-and-down direction VD. Thus, in the connector 10, the housing 100 consists of two portions (i.e., first and second housings 131 and 132). The second housing 132 is stacked on the first housing 131, and a lower surface of the second housing 132 and an upper surface of the first housing 131 may be bonded to each other by an adhesive. The second housing 132 may have a thickness less than an up-and-down directional thickness of the first housing 131, for example, a thickness as thick as a thickness of the air insulation portion 400.

The first through hole 110, in which the signal conduction portion 200 is disposed, is formed by portions of the first through hole formed in the respective housings stacked in the up-and-down direction. A portion 111 of the first through hole 110 is formed in the first housing 131, and the remainder portion 112 of the first through hole 110 is formed in the second housing 132. The insulation support portion 300 is disposed in the portion 111 of the first through hole, and supports the signal conduction portion 200 coaxially with the central axis CA. Therefore, the concealed portion 220 of the signal conduction portion 200 is disposed in the portion 111 of the first through hole. The exposed portion 230 of the signal conduction portion 200 is not disposed in the portion 111 of the first through hole. When the first housing and the second housing 132 are stacked in the up-and-down direction, the exposed portion 230 of the signal conduction portion is disposed in the remainder portion 112 of the first through hole.

In the state where the first and second housings 131 and 132 are stacked in the up-and-down direction VD as shown in FIG. 18, the air insulation portion 400 is formed so as to surround the exposed portion 230 of the signal conduction portion. The air insulation portion 400 may be formed by the outer peripheral surface of the exposed portion 230, the upper surface of the insulation support portion 300, and an inner peripheral surface of the remainder portion 112 of the first through hole. The remainder portion 112 of the first through hole is formed in the second housing 132, and the insulation support portion 300 is not disposed in the remainder portion 112. As the first and second housings 131 and 132 are stacked, the first through hole 110 of the housing 100 is completely formed, and the air insulation portion 400 is formed by the remainder portion 112 of the first through hole in which the insulation support portion 300 is not disposed. Accordingly, in the connector 10 in which two portions are stacked to form the housing 100, the air insulation portion can be easily formed in the first through hole.

In the connector 10 shown in FIGS. 18 and 19, the ground conduction portion 600 is disposed in the housing 100. As another embodiment, the housing of the connector shown in FIGS. 2 and 3, in which the ground conduction portion is not disposed, may consist of the above-described first and second housings.

In the connector in which the ground conduction portion is disposed in the housing, the second through hole 120 has a portion 121 formed in the first housing 131, and a remainder portion 122 formed in the second housing 132. Therefore, the ground conduction portion 600 includes a first portion 631 disposed in the portion 121 of the second through hole of the first housing, and a second portion 632 disposed in the remainder portion 122 of the second through hole of the second housing. The first portion 631 and the second portion 632 are bonded in the up-and-down direction VD, constituting the ground conduction portion 600. The ground conduction portion 600 includes the above-described second conductive particles. An adhesive may be applied only to an upper surface of the first housing 131 and a lower surface of the second housing 132. To increase a contact force between the second conductive particles of the first portion 631 and the second conductive particles of the second portion 632, an upper end surface of the first portion 631 and a lower end surface of the second portion 632 may be modified by means of irradiation of UV. The first and second portions 631 and 632 include a second elastic material maintaining the second conductive particles. Due to the irradiation of UV, the second elastic material of the first and second portions 631 and 632 can be modified such that molecules of the elastic material have adhesive functional group. The molecules of the elastic material of the first portion 631 and the molecules of the elastic material of the second portion 632 are chemically bonded via the adhesive functional group, thereby bonding the first portion 631 and the second portion 632.

FIG. 20 is a sectional view showing another example of the connector according to the seventh embodiment. Referring to FIG. 20, the exposed portion 230 of the signal conduction portion has a diameter greater than a diameter of the concealed portion 220. In the state where the first and second housings 131 and 132 are stacked in the up-and-down direction, the exposed portion 230 of the signal conduction portion is disposed in the remainder portion 112 of the first through hole of the second housing, and the air insulation portion 400 is formed so as to surround the exposed portion 230.

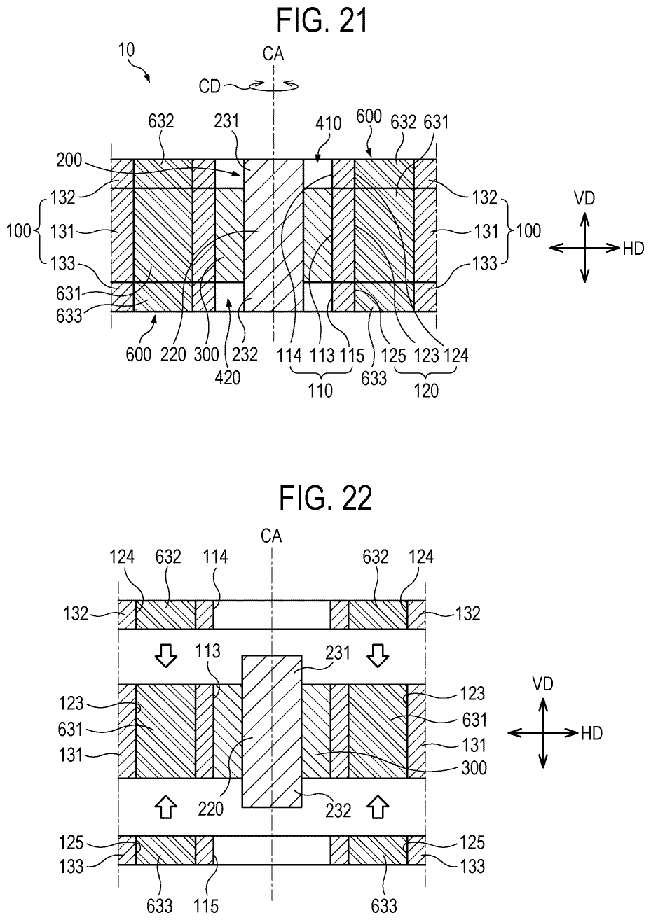

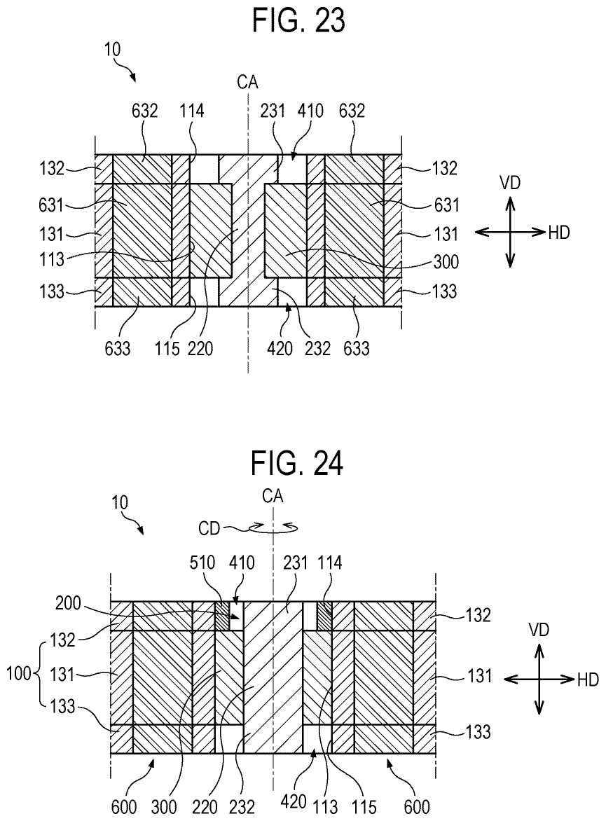

FIG. 21 is a sectional view showing a portion of a connector according to an eighth embodiment of the present disclosure, and FIG. 22 is an exploded sectional view showing the portion of the connector shown in FIG. 21. FIG. 23 is a sectional view showing another example of the connector according to the eighth embodiment. Reference is made to FIGS. 21 to 23 for descriptions of the connector according to the eighth embodiment.

The connector according to the eighth embodiment has a configuration similar to the configuration of the connector described with reference to FIG. 5, and includes the ground conduction portion of the connector of the embodiment described with reference to FIG. 13. In the connector 10 according to the eighth embodiment, the housing 100 has a structure where three portions are stacked. Therefore, the air insulation portion decreasing the dielectric permittivity in the signal transmission of the signal conduction portion can be easily formed in the upper end and the lower end of the first through hole of the housing due to the stacked structure of the housing.

Referring to FIGS. 21 and 22, the housing 100 includes first, second, and third housings 131, 132, and 133 that are stacked in the up-and-down direction VD. Thus, in the connector 10, the housing 100 consists of three portions (i.e., the first, second, and third housings 131, 132, and 133). The second housing 132 is stacked on the first housing 131, and the lower surface of the second housing 132 and the upper surface of the first housing 131 may be bonded to each other by an adhesive. The third housing 133 is stacked under the first housing 131, and an upper surface of the third housing 133 and a lower surface of the first housing 131 may be bonded to each other by an adhesive. The second housing 132 and the third housing 133 have a thickness less than the up-and-down directional thickness of the first housing 131. For example, the second housing 132 may have a thickness as thick as a thickness of the first air insulation portion 410, and the third housing 133 may have a thickness as thick as a thickness of the second air insulation portion 420.

The first through hole 110, in which the signal conduction portion 200 is disposed, is formed by portions of the first through hole formed in the respective housings stacked in the up-and-down direction. An intermediate portion 113 of the first through hole 110 is formed in the first housing 131, an upper portion 114 located on the intermediate portion 113 of the first through hole is formed in the second housing 132, and a lower portion 115 located under the intermediate portion 113 of the first through hole is formed in the third housing 133. The insulation support portion 300 is disposed in the intermediate portion 113 of the first through hole, and supports the signal conduction portion 200 coaxially with the central axis CA. Therefore, the concealed portion 220 of the signal conduction portion 200 is disposed in the intermediate portion 113 of the fist through hole. The exposed portion of the signal conduction portion 200 is not disposed in the intermediate portion 113 of the fist through hole. The exposed portion of the signal conduction portion includes the first exposed portion 231 disposed at the upper end of the first through hole, and the second exposed portion 232 disposed at the lower end of the first through hole. When the first, second, and third housings 131, 132, and 133 are stacked in the up-and-down direction, the first exposed portion 231 of the signal conduction portion is disposed in the upper portion 114 of the first through hole, and the second exposed portion 232 of the signal conduction portion is disposed in the lower portion 115 of the first through hole.

In the state where the first, second, and third housings 131, 132, and 133 are stacked in the up-and-down direction VD as shown in FIG. 21, the first air insulation portion 410 is formed so as to surround the first exposed portion 231 of the signal conduction portion, and the second air insulation portion 420 is formed so as to surround the second exposed portion 232 of the signal conduction portion. The first air insulation portion 410 may be formed by the outer peripheral surface of the first exposed portion 231, the upper surface of the insulation support portion 300, and an inner peripheral surface of the upper portion 114 of the first through hole. The second air insulation portion 420 may be formed by the outer peripheral surface of the second exposed portion 232, the lower surface of the insulation support portion 300, and an inner peripheral surface of the lower portion 115 of the first through hole. The insulation support portion 300 is disposed only in the intermediate portion 113 of the first through hole. As the first, second, and third housings 131, 132, and 133 are stacked, the first through hole 110 of the housing 100 is completely formed, and the first air insulation portion 410 and the second air insulation portion 420 are formed by the upper portion 114 and the lower portion 115 of the first through hole in which the insulation support portion 300 is not disposed, respectively. Accordingly, in the connector 10 in which three portions are stacked to form the housing 100, the air insulation portion can be easily formed at the upper end and the lower end of the first through hole.

In the connector 10 shown in FIGS. 21 and 22, the ground conduction portion 600 is disposed in the housing 100. As another embodiment, the housing of the connector shown in FIGS. 5 and 7, in which the ground conduction portion is not disposed, may consist of the above-described first, second, and third housings.

In the connector in which the ground conduction portion is disposed in the housing, the second through hole 120 has an intermediate portion 123 formed in the first housing 131, an upper portion 124 formed in the second housing 132, and a lower portion 125 formed in the third housing 133. Therefore, the ground conduction portion 600 includes a first portion 631 disposed in the intermediate portion 123 of the second through hole of the first housing, a second portion 632 disposed in the upper portion 124 of the second through hole of the second housing, and a third portion 633 disposed in the lower portion 125 of the second through hole of the third housing. The first portion 631 and the second portion 632 are bonded in the up-and-down direction VD, and the first portion 631 and the third portion 633 are bonded in the up-and-down direction VD, thereby constituting the ground conduction portion 600. When the first, second, and third housings 131, 132, and 133 are stacked, an adhesive may be applied only to the upper and lower surfaces of the first housing 131, the lower surface of the second housing 132, and the upper surface of the third housing 133. For bonding of the first portion 631, the second portion 632, and the third portion 633 constituting the ground conduction portion 600 in the up-and-down direction, the above-described modification caused by the irradiation of UV may be used to form the adhesive functional group in the molecules of the elastic material.

FIG. 23 is a sectional view showing another example of the connector according to the eighth embodiment. Referring to FIG. 23, the first exposed portion 231 and the second exposed portion 232 of the signal conduction portion have a diameter greater than the diameter of the concealed portion 220. In the state where the first, second, and third housings 131, 132, and 133 are stacked in the up-and-down direction, the first exposed portion 231 is disposed in the upper portion 114 of the first through hole of the second housing, and the second exposed portion 232 is disposed in the lower portion 115 of the first through hole of the third housing. Further, the first air insulation portion 410 is formed so as to surround the first exposed portion 231, and the second air insulation portion 420 is formed so as to surround the second exposed portion 232.

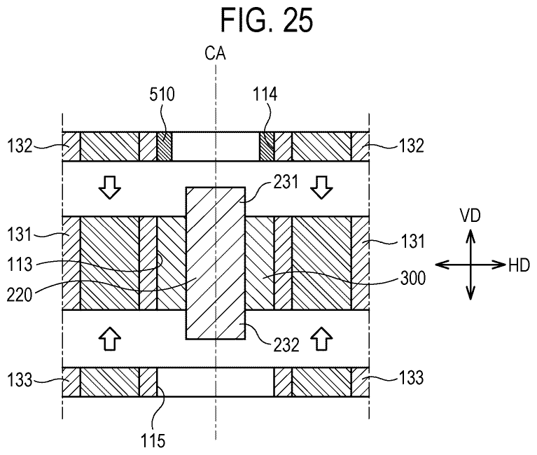

FIG. 24 is a sectional view showing a portion of a connector according to a ninth embodiment of the present disclosure, and FIG. 25 is an exploded sectional view showing the portion of the connector shown in FIG. 24. Reference is made to FIGS. 24 and 25 for descriptions of the connector according to the ninth embodiment.

The connector 10 according to the ninth embodiment has a configuration similar to the configuration of the connector according to the eighth embodiment described with reference to FIGS. 21 to 23. The connector 10 according to the ninth embodiment includes the elastic portion 510 that is formed along the inner peripheral surface of the upper portion 114 of the first through hole of the second housing 132. The elastic portion 510 can prevent damage to the terminal of the device under test (e.g., the signal terminal 31 of the device under test shown in FIG. 1).

The elastic portion 510 has the same configuration as the configuration of the elastic portion described with reference to FIGS. 8 and 9. The elastic portion 510 is disposed in the second housing 132 stacked on the first housing 131, and is formed in the upper portion 114 of the first through hole of the second housing. Thus, the elastic portion 510, which can prevent damage to the signal terminal of the device under test, can be easily provided in the connector having the housing 100 of a stacked structure.

The elastic portion 510 may be applied to the connector shown in FIGS. 18 to 20, in which the housing consists of the first and second housings. The elastic portion 510 may be formed in the remainder portion 112 of the first through hole in FIGS. 18 to 20. By way of example, to form an elastic object filling the remainder portion 112 of the first through hole or the upper portion 114 of the first through hole, the elastic material of the elastic portion (or the elastic material containing a foaming agent) may be injected into and hardened in the remainder portion 112 of the first through hole or the upper portion 114 of the first through hole.

Thereafter, a through hole is formed in the elastic object in the up-and-down direction by a laser, and the second housing 132 provided with the elastic portion 510 may be prepared thereby. As the second housing 132 is stacked on the first housing 131, the elastic portion 510 spaced apart from the outer peripheral surface of the signal conduction portion (e.g., the outer peripheral surface of the first exposed portion 231) may be provided in the connector. Further, the elastic portion 520 containing the pores shown in FIG. 11 may be provided in the connector by a method similar to the method of providing the above-described elastic portion 510 in the second housing.

In the connector shown in FIGS. 18 to 25, the housing 100 has a stacked structure, and therefore, the air insulation portion can be easily formed in the first through hole 110.

By way of example, in a state where the upper surface and the lower surface of the first housing 131 is covered by a molding die, the liquid molding material, in which the above-described first conductive particles are dispersed in the above-described first elastic material of a liquid state, may be injected into the portion 111 or the intermediate portion 113 of the first through hole. Thereafter, the first conductive particles are gathered in the up-and-down direction by application of a magnetic field, and the signal conduction portion and the insulation support portion may be molded thereby. Thereafter, the liquid molding material is injected to another molding die, and the exposed portion located on and under the concealed portion may be molded by application of a magnetic field. In this case, if a cylindrical hole greater than a diameter of the concealed portion is provided in the aforementioned another molding die, the exposed portion having a diameter greater than the diameter of the concealed portion may be molded.

By way of another example, to form an elastic object filling the portion 111 or the intermediate portion 113 of the first through hole, the liquid molding material constituting the insulation support portion may be injected and hardened. Thereafter, a through hole may be formed in the up-and-down direction in the elastic object by a laser. Thereafter, a molding die covering the through hole of the elastic object may be installed, and the liquid molding material, in which the above-described first conductive particles are dispersed in the above-described first elastic material of a liquid state, may be injected into the through hole. Thereafter, the first conductive particles are gathered in the up-and-down direction by application of a magnetic field, and the signal conduction portion supported by the insulation support portion may be molded thereby. In this case, if a cylindrical hole greater than a diameter of the concealed portion is provided in the aforementioned another molding die, the exposed portion having a diameter greater than the diameter of the concealed portion may be molded.

The technical idea of the present disclosure has been described heretofore with reference to some embodiments and examples shown in the accompanying drawings. However, it is to be understood that various substitutions, modifications, and alterations may be made without departing from the technical idea and scope of the present disclosure that can be understood by those of ordinary skill in the technical field to which the present disclosure pertains. Further, it is to be understood that such substitutions, modifications, and alterations fall within the scope of the appended claims.

1. A test connector disposed between a test apparatus and a device under test, comprising:
a housing having a first through hole perforated in an up-and-down direction;
a signal conduction portion configured to be conductive in the up-and-down direction and disposed in the first through hole in the up-and-down direction so as to be spaced apart from an inner peripheral surface of the first through hole;
an insulation support portion formed between the first through hole and the signal conduction portion so as to surround the signal conduction portion in a circumferential direction with respect to a central axis of the first through hole, and configured to support and insulate the signal conduction portion such that the signal conduction portion is positioned coaxially with the central axis, wherein the insulation support portion has an up-and-down directional thickness less than an up-and-down directional thickness of the housing; and
an air insulation portion located between the inner peripheral surface of the first through hole and an outer peripheral surface of the signal conduction portion, wherein the air insulation portion is a space formed by the inner peripheral surface of the first through hole, the outer peripheral surface of the signal conduction portion, and an upper surface or a lower surface of the insulation support portion.

2. The connector of claim 1, wherein the air insulation portion is formed as an annular groove that surrounds the outer peripheral surface of the signal conduction portion in the circumferential direction at least one of an upper end or a lower end of the first through hole.

3. The connector of claim 1, wherein the air insulation portion includes a first air insulation portion and a second air insulation portion, which are located at an upper end and a lower end of the first through hole, respectively, and
wherein the connector further comprises an elastic portion that is formed in the first air insulation portion along the inner peripheral surface of the first through hole so as to be spaced apart from the outer peripheral surface of the signal conduction portion.

4. The connector of claim 3, wherein the elastic portion is made of silicone rubber or silicone rubber containing a multiple number of pores.

5. The connector of claim 1, wherein the air insulation portion includes a first air insulation portion and a second air insulation portion, which are located at an upper end and a lower end of the first through hole, respectively, and
wherein the connector further comprises an elastic portion, which is disposed in the first air insulation portion so as to surround the outer peripheral surface of the signal conduction portion and contains a multiple number of pores.

6. The connector of claim 1, wherein the housing has a second through hole, which is spaced apart from the first through hole in a horizontal direction and is perforated in the up-and-down direction, and
wherein the connector further comprises a ground conduction portion, which is disposed in the second through hole in the up-and-down direction and is configured to be conductive in the up-and-down direction.

7. The connector of claim 6, wherein an upper end of the ground conduction portion protrudes with respect to an upper surface of the housing and a lower end of the ground conduction portion protrudes with respect to a lower surface of the housing.

8. The connector of claim 6, wherein the signal conduction portion comprises a multiple number of first conductive particles gathered so as to be capable of conducting in the up-and-down direction, and a first elastic substance maintaining the multiple number of first conductive particles in the up-and-down direction, and
wherein the ground conduction portion comprises a multiple number of second conductive particles gathered so as to be capable of conducting in the up-and-down direction, and a second elastic substance maintaining the multiple number of second conductive particles in the up-and-down direction.

9. The connector of claim 1, further comprising an insulation sheet coupled to a portion in a vicinity of a lower end of the signal conduction portion to support the signal conduction portion in the up-and-down direction, and coupled to a lower surface of the housing,
wherein the insulation support portion and the signal conduction portion are integrally formed and the signal conduction portion and the insulation sheet are integrally formed, thereby constituting a conduction module that is removably coupled to the housing, and
wherein the insulation support portion is fitted into the first through hole.

10. The connector of claim 1, wherein the signal conduction portion includes:
a concealed portion surrounded by the insulation support portion; and
an exposed portion not surrounded by the insulation support portion and surrounded by the air insulation portion, wherein the exposed portion has a diameter equal to or greater than a diameter of the concealed portion and forms an upper end or a lower end of the signal conduction portion.

11. The connector of claim 10, wherein the diameter of the exposed portion is in a range of 1 times to less than or equal to 2.5 times the diameter of the concealed portion.

12. The connector of claim 10, wherein the housing includes first and second housings that are stacked and bonded in the up-and-down direction,
wherein a portion of the first through hole is formed in the first housing and a remainder portion of the first through hole is formed in the second housing,
wherein the insulation support portion and the concealed portion are disposed in the portion of the first through hole and the exposed portion is disposed in the remainder portion of the first through hole, and
wherein the air insulation portion is formed to surround the exposed portion in a state where the first and second housings are stacked in the up-and-down direction.

13. The connector of claim 12, wherein the housing has a second through hole, which is spaced apart from the first through hole in a horizontal direction and is perforated in the up-and-down direction,
wherein the connector further comprises a ground conduction portion, which is disposed in the second through hole in the up-and-down direction and is configured to be conductive in the up-and-down direction, and
wherein the ground conduction portion includes a first portion disposed in the first housing, and a second portion disposed in the second housing and bonded to the first portion.

14. The connector of claim 10, wherein the housing includes first, second, and third housings that are stacked and bonded in the up-and-down direction,
wherein an intermediate portion of the first through hole is formed in the first housing, an upper portion of the first through hole located on the intermediate portion is formed in the second housing, and a lower portion of the first through hole located under the intermediate portion is formed in the third housing,
wherein the insulation support portion and the concealed portion are disposed in the intermediate portion of the first through hole and the exposed portion is disposed in the upper portion of the first through hole and the lower portion of the first through hole, and
wherein the air insulation portion is formed so as to surround the exposed portion in a state where the first, second, and third housings are stacked in the up-and-down direction.

15. The connector of claim 14, wherein the housing has a second through hole, which is spaced apart from the first through hole in a horizontal direction and is perforated in the up-and-down direction,
wherein the connector further comprises a ground conduction portion, which is disposed in the second through hole in the up-and-down direction and is configured to be conductive in the up-and-down direction, and
wherein the ground conduction portion includes a first portion disposed in the first housing, a second portion disposed in the second housing and bonded to the first portion, and a third portion disposed in the third housing and bonded to the first portion.

16. The connector of claim 14, further comprising an elastic portion that is formed along an inner peripheral surface of the upper portion of the first through hole of the second housing so as to be spaced apart from the outer peripheral surface of the signal conduction portion.

17. The connector of claim 1, wherein the up-and-down directional thickness of the insulation support portion is in a range of 50% to 90% of the up-and-down directional thickness of the housing.

18. The connector of claim 1, wherein the insulation support portion is made of one of silicone rubber, polyimide resin, polyetherimide resin, and polytetrafluoroethylene resin.

19. The connector of claim 1, wherein the housing is made of a metallic material or nonmetallic material, and
wherein the metallic material is aluminum or stainless steel and the nonmetallic material is polyimide resin or standard epoxy resin.
